(19) United States
(12) Patent Application Publication
(10) Pub. No.: US 2016/0064685 A1
(43) Pub. Date: Mar. 3, 2016

(54) PROTECTION STRUCTURE AND ORGANIC LIGHT EMITTING DISPLAY DEVICE INCLUDING THE PROTECTION STRUCTURE

(71) Applicant: Samsung Display Co., Ltd., Yongin-city (KR)

(72) Inventor: Beong-Ju KIM, Cheonan-si (KR)

(21) Appl. No.: 14/621,184

(22) Filed: Feb. 12, 2015

(30) Foreign Application Priority Data
Aug. 26, 2014 (KR) 10-2014-0111768

(51) Int. Cl. H01L 51/52; B32B 5/12; B32B 3/26

(52) U.S. Cl. CPC H01L 51/5237; B32B 3/266; B32B 5/12; H01L 2251/5338; B32B 2255/06; B32B 2255/10; B32B 2255/02; B32B 2255/26; B32B 2307/51; B32B 2457/206; B32B 2571/00

(57) ABSTRACT

A protection structure including a first elastic layer, a supporting layer, and a second elastic layer. The supporting layer is disposed on the first elastic layer. The supporting layer includes a plurality of openings. The second elastic layer fills the openings. The second elastic layer is combined with the first elastic layer.

### CROSS REFERENCE TO RELATED APPLICATION

This application claims priority from and the benefit of Korean patent Application No. 10-2014-0111768 filed on Aug. 26, 2014, which is hereby incorporated by reference for all purposes as if fully set forth herein.

### BACKGROUND

1. Field

Exemplary embodiments relate to protection structures and organic light emitting display devices including the protection structures. More particularly, exemplary embodiments relate to protection structures including an elastic layer and a supporting layer and organic light emitting display devices including the protection structures.

2. Discussion of the Background

A flat panel display (FPD) device is widely used as a display device of an electronic device because the FPD device is lightweight and thin compared to a cathode-ray tube (CRT) display device. Typical examples of the FPD device are a liquid crystal display (LCD) device and an organic light emitting display (OLED) device. Compared to the LCD device, the OLED device has many advantages such as a higher luminance and a wider viewing angle. In addition, the OLED device can be made thinner because the OLED device does not require a backlight. In the OLED device, electrons and holes are injected into an organic thin layer through a cathode and an anode, and then recombined in the organic thin layer to generate excitons, thereby emitting a light of a certain wavelength.

Recently, as the OLED device includes lower and upper substrates having flexibility, a flexible OLED device capable of bending or folding the OLED device has been developed. In this case, such material as polyimide may be used as lower substrate. The upper substrate may be formed by alternately stacking inorganic and organic layers. Thus, the OLED device including the lower and upper substrates may have flexibility. However, the lower and upper substrates of a conventional flexible OLED device may not have high resilience or high elasticity. As a result, it is difficult to make a flexible OLED display device that can be restored from a transformed state (e.g., folding or bending states) into an original state.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide protection structures capable of increasing elasticity while maintaining mechanical strength by including a supporting layer and an elastic layer.

Exemplary embodiments provide organic light emitting display devices having protection structures that can increase elasticity while maintaining mechanical strength by including a supporting layer and an elastic layer.

Additional aspects will be set forth in the detailed description which follows, and, in part, will be apparent from the disclosure, or may be learned by practice of the inventive concept.

According to exemplary embodiments, there is provided a protection structure including a first elastic layer, a supporting layer, and a second elastic layer. The supporting layer including a plurality of openings is disposed on the first elastic layer. The second elastic layer fills the openings of the supporting layer, and is combined with the first elastic layer.

In exemplary embodiments, the supporting layer may include metal or plastic.

In exemplary embodiments, each of the first elastic layer and the second elastic layer may include elastic materials.

In exemplary embodiments, the first elastic layer and the second elastic layer may include the same material.

In exemplary embodiments, the supporting layer may have a plate structure.

In exemplary embodiments, each of the openings of the supporting layer may have one selected from the group of a planar shape of a square opening shape, a rectangular opening shape and a diamond opening shape.

In exemplary embodiments, the supporting layer may include a plurality of support lines that are regularly crossed.

In exemplary embodiments, the support lines include a plurality of first support lines and a plurality of second support lines.

In exemplary embodiments, the first support lines may have a first thickness and a first width.

In exemplary embodiments, the first support lines may extend along a first direction.

In exemplary embodiments, the first support lines may be spaced apart from each other by a first distance.

In exemplary embodiments, the second support lines may have a second thickness and a second width.

In exemplary embodiments, the second support lines may extend along a second direction that is perpendicular to the first direction.

In exemplary embodiments, the second support lines may be spaced apart from each other by a second distance.

In exemplary embodiments, the second support lines may be disposed on the first support lines.

In exemplary embodiments, the first support lines and the second support lines may define a plurality of openings.

In exemplary embodiments, the openings may be regularly arranged.

In exemplary embodiments, the openings may have one selected from the group of a planar shape of a square opening shape, a rectangular opening shape, and a diamond opening is shape.

In exemplary embodiments, the supporting layer may further include a border line.

In exemplary embodiments, the border line may be connected to end portions of the first support lines and the second support lines.

In exemplary embodiments, the border line may surround the first support lines and the second support lines.

In exemplary embodiments, the supporting layer may include a plurality of support lines that are irregularly crossed.

In exemplary embodiments, the support lines may further include a plurality of third support lines.

In exemplary embodiments, the third support lines may have a third thickness and a third width.

In exemplary embodiments, the third support lines may extend along A direction different from the first direction and the second direction.

In exemplary embodiments, the third support lines may be spaced apart from each other by a third distance.

In exemplary embodiments, the support lines may further include a plurality of fourth support lines may have a fourth thickness and a fourth width.

In exemplary embodiments, the fourth support lines may extend along B direction perpendicular to the A direction.

In exemplary embodiments, the fourth support lines may be spaced apart from each other by a fourth distance.

In exemplary embodiments, the first support lines through the fourth support lines may define a plurality of openings, and the openings are irregularly arranged.

In exemplary embodiments, a thickness of each of the first through the fourth support lines may be smaller than a width of each of the first through the fourth support lines.

In exemplary embodiments, the openings may have one selected from the group of a planar shape of a triangle opening shape, a circular opening shape, an elliptical opening shape and a track-like opening shape.

According to some aspect of exemplary embodiments, an organic light emitting display device includes a protection structure, a substrate disposed on the protection structure, a light emitting structure, and an encapsulation substrate. The protection structure includes a first elastic layer, a supporting layer disposed on the first elastic layer, and a second elastic layer filling the openings. The supporting layer includes a plurality of openings, and is combined with the first elastic layer. The light emitting structure is disposed on the substrate disposed on the protection structure. The encapsulation substrate is disposed on the light emitting structure.

In exemplary embodiments, the organic light emitting display device may further include an adhesion film disposed between the protection structure and the substrate disposed on the protection structure.

In exemplary embodiments, the substrate disposed on the protection structure and the encapsulation substrate may include materials having flexibility. The exemplary embodiments provide the protection structure that includes the supporting layer and the elastic layer, and may increase elasticity or resilience.

According to exemplary embodiments, as the organic light emitting display device includes the protection structure having the supporting layer and the elastic layer, elasticity or resilience may be increased.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a cross-sectional view illustrating a protection structure in accordance with exemplary embodiments.

FIG. 2 is a plan view illustrating a protection structure in accordance with exemplary embodiments.

FIG. 3 is a perspective view for describing a supporting layer of the protection structure illustrated in FIG. 1.

FIG. 4 is a perspective view for describing another example of the supporting layer illustrated in FIG. 3.

FIG. 5 is a cross-sectional view illustrating a protection structure in accordance with some exemplary embodiments.

FIG. 6 is a perspective view for describing a supporting layer of the protection structure illustrated in FIG. 5.

FIG. 7 is a perspective view illustrating a protection structure in accordance with is some exemplary embodiments.

FIG. 8 is a cross-sectional view illustrating an organic light emitting display device in accordance with exemplary embodiments.

FIGS. 9A to 9H are cross-sectional views illustrating a method of manufacturing an organic light emitting display device in accordance with exemplary embodiments.

### DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, is Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

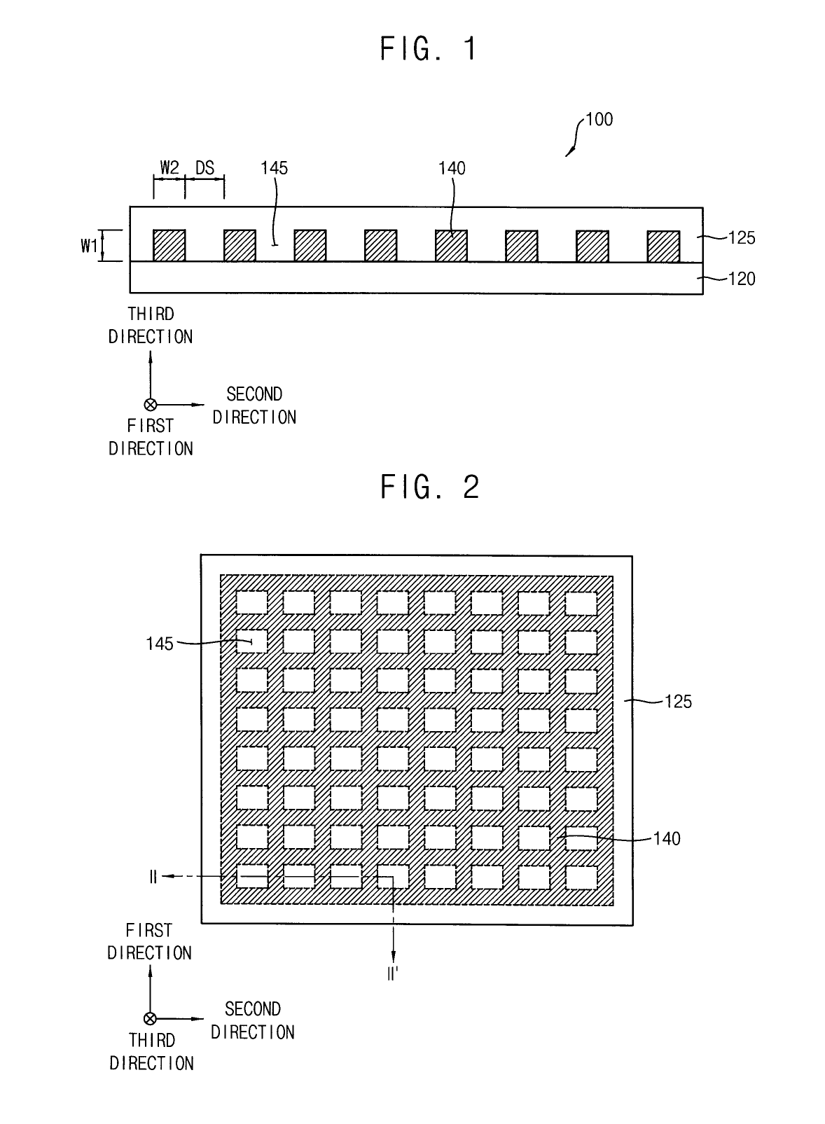

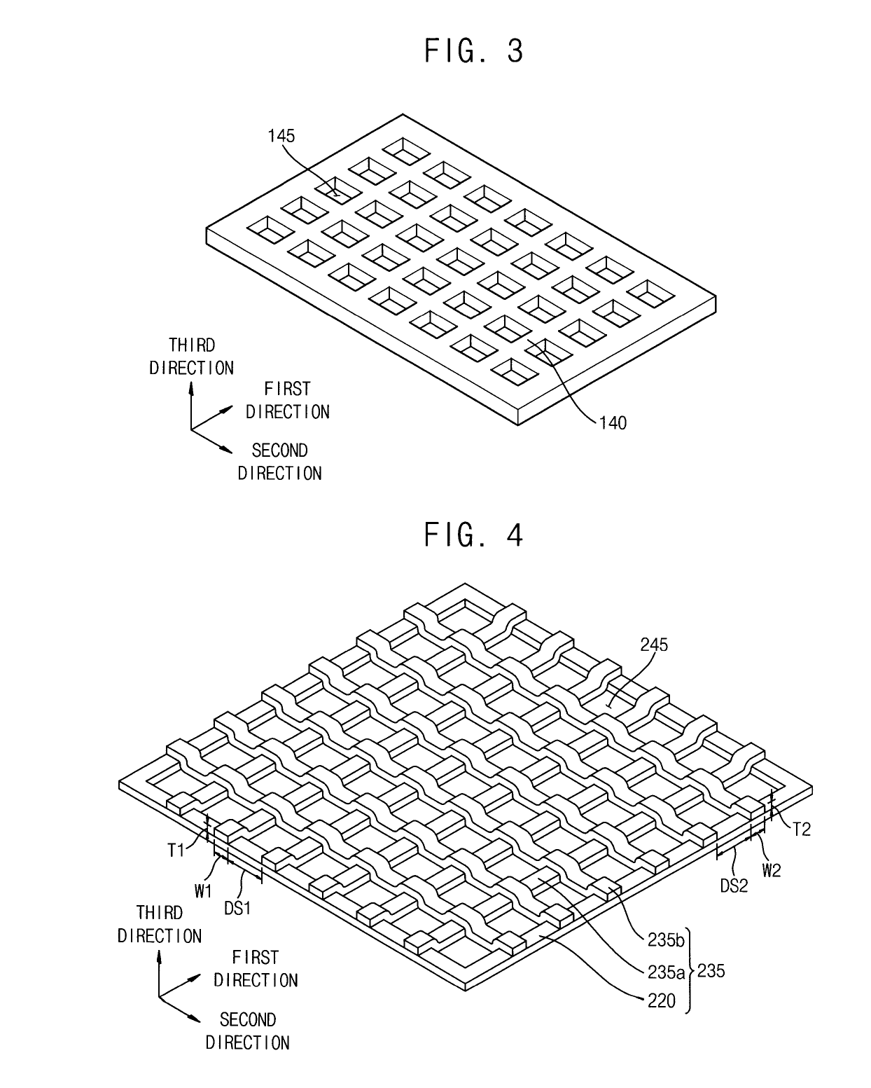

FIG. 1 is a cross-sectional view illustrating a protection structure in accordance with some exemplary embodiments, and FIG. 2 is a plan view illustrating a protection structure in accordance with some exemplary embodiments. FIG. 3 is a perspective view for describing a supporting layer of the protection structure illustrated in FIG. 1.

Referring to FIGS. 1 through 3, a protection structure 100 may include a first elastic layer 120, a supporting layer 140, and a second elastic layer 125. In exemplary embodiments, the supporting layer 140 may be interposed between the first elastic layer 120 and the second elastic layer 125. For example, the first and second elastic layers 120 and 125 may substantially surround the supporting layer 140. Accordingly, the supporting layer 140 may be buried between the first and second elastic layers 120 and 125.

In exemplary embodiments, the supporting layer 140 of the protection structure 100 may substantially have a plate-shape. In this case, the supporting layer 140 may include a plurality of openings 145. For example, the openings 145 of the supporting layer 140 may be substantially regularly arranged along a column direction or a row direction. Each of the openings 145 illustrated in FIGS. 1 through 3 substantially has a planar shape of a substantially rectangular shape, but a shape of the openings 145 is not limited thereto. For example, each of the openings 145 of the supporting layer 140 may have various planar shapes such as a planar shape of a substantially square opening shape, a substantially diamond opening shape, a substantially triangle opening shape, a substantially circular opening shape, a substantially elliptical opening shape, a substantially track-like opening shape, etc.

As illustrated in FIG. 1, each of the openings 145 of the supporting layer 140 may be regularly arranged along a first direction and a second direction substantially perpendicular to the first direction. In addition, the supporting layer 140 may have a first width W1 along a third direction substantially perpendicular to the first direction, and may have a second width W2 along the second direction substantially perpendicular to the third direction. For example, each of the openings 145 of the supporting layer 140 may have different widths along a column direction and a row direction. In addition, openings 145 may have a distance DS. The distance DS may be different from the first width W1 of the supporting layer 140 and/or the second width W2 of the supporting layer 140. For example, the distance DS of openings 145 may be substantially smaller than the first width W1 of the supporting layer 140 and/or the second width W2 of the supporting layer 140. However, the distance DS of the openings 145 may be increased or decreased according to a shape of the openings 145.

As illustrated in FIG. 2, the supporting layer 140 may be positioned in the first and second elastic layers 120 and 125. In this case, a plurality of the openings 145 of the supporting layer 140 may be filled with the first and second elastic layers 120 and 125. For example, since the openings 145 are filled with the first and second elastic layers 120 and 125 in a vacuum state, air may not exist in the openings 145. The supporting layer 140 may have a substantially mesh structure. For example, the openings 145 may be formed in a preliminary metal plate by an etching process using a mask. The metal plate including the openings 145 may be the supporting layer 140 in accordance with exemplary embodiments. Accordingly, as the protection structure 100 includes the supporting layer 140 having the mesh structure and the first and second elastic layers 120 and 125 in which the supporting layer 140 is buried, resilience or elasticity may be relatively increased.

The supporting layer 140 may include material such as a metal or a supporting plastic, having a relatively high resilience or a relatively high elasticity. For example, the supporting layer 140 may include an alloy (e.g., a super elastic metal) such as nickel-titanium (Ni—Ti), nickel-aluminum (Ni—Al), copper-zinc-nickel (Cu—Zn—Ni), copper-Aluminum-Nickel (Cu—Al—Ni), copper-aluminum-manganese (Cu—Al—Mn), titanium-nickel-copper-molybdenum (Ti—Ni—Cu—Mo), cobalt-nickel-gallium:iron (Co—Ni—Ga:Fe), silver-nickel (Ag—Ni), gold-cadmium (Au—Cd), iron-platinum (Fe—Pt), iron-nickel (Fe—Ni), indium-cadmium (In—Cd), and so on. Alternately, the supporting layer 140 may include metal nitride, conductive metal oxide, a transparent conductive material, and others. For example, the supporting layer 140 may include aluminum alloy, aluminum nitride (AlNx), silver alloy, tungsten nitride (WNx), copper alloy, chrome nitride (CrNx), molybdenum alloy, titanium nitride (TiNx), tantalum nitride (TaNx), strontium ruthenium oxide (SRO), zinc oxide (ZnOx), indium tin oxide (ITO), stannum oxide (SnOx), indium oxide (InOx), gallium oxide (GaOx), indium zinc oxide (IZO), and the similar. In addition, the first and second elastic layers 120 and 125 may include an elastomer having a relatively high resilience or a relatively high elasticity. For example, the first and second elastic layers 120 and 125 may include elastic materials such as silicon, urethane, thermoplastic poly urethane (TPU), etc. When the first elastic layer 120 includes materials the same as materials of the second elastic layer 125, the first elastic layer 120 may be substantially integrally formed with the second elastic layer 125. In exemplary embodiments, when the supporting layer 140 illustrated in FIG. 3 directly adheres to a lower substrate of an organic light emitting display (OLED) device by using a pressure sensitive adhesive (PSA) film, the supporting layer 140 and the lower substrate may not be bonded because materials of the supporting layer 140 is different from materials of the lower substrate. For example, the PSA film may include materials the same as materials of the first elastic layer 120 and the second elastic layer 125. In addition, since the lower substrate is relatively thinner than the supporting layer 140, the supporting layer 140 may not be substantially buried in the lower substrate. However, when a thickness of the lower substrate is increased and the supporting layer 140 is buried in the lower substrate, the supporting layer 140 buried in the lower substrate while an light emitting structure is formed on the lower substrate may cause a problem. Thus, after the light emitting structure is formed on the lower substrate, the protection structure 100 including the supporting layer 140 buried in the first and second elastic layers 120 and 125 may adhere to a lower surface of the lower substrate by using the PSA film.

FIG. 4 is a perspective view for describing another example of the supporting layer illustrated in FIG. 3. A supporting layer 235 illustrated in FIG. 4 may have a configuration substantially the same as or similar to that of the supporting layer 140 described with reference to FIGS. 1 through 3. In FIG. 4, detailed descriptions for elements, which are substantially the same as or similar to the elements described with reference to FIGS. 1 through 3, will be omitted.

Referring to FIG. 4, a protection structure may include a supporting layer 235 and an elastic layer. Here, the supporting layer 235 may include a plurality of supporting lines. A plurality of openings 245 may be defined by the supporting lines. In other word, the supporting layer 235 may include a configuration that one opening 245 is disposed between adjacent two of the supporting lines. The plurality of supporting lines may include a plurality of first support lines 235a and a plurality of second support lines 235b. The first support lines 235a may have a first thickness T1 and a first width W1. The first support lines 235a may extend along a first direction (e.g., a column direction). Adjacent first support lines 235a may be spaced apart by a first distance DS1, and may be arranged in substantially parallel to each other.

The second support lines 235b may have a second thickness T2 and a second width W2. The second support lines 235b may extend along a second direction that is substantially perpendicular to the first direction (e.g., a row direction). Adjacent second support lines 235b may be spaced apart by a second distance DS2, and may be arranged in substantially parallel to each other. In addition, the second support lines 235b may be disposed on the first support lines 235a. Further, the first support lines 235a and the second support lines 235b may be arranged to cross each other. Accordingly, the supporting layer 235 including the first support lines 235a and the second support lines 235b may substantially have a mesh structure.

A border line 220 may be connected to end portions of the first and second support lines 235a and 235b. The end portions may be substantially disposed on the border line 220. The border line 220 may include a planar shape of a rectangular shape or a square shape. For example, after the border line 220 is disposed, the first support lines 235a may be disposed on the border line 220 by connecting the end portions of the first support lines 235b to the border line 220 (e.g., a compression in the vacuum). Next, the second support lines 235b may be disposed on the border line 220 by connecting the end portions of the second support lines 235b to the border line 220. In this case, the first support lines 235a and the second support lines 235b may be crossed to each other.

In exemplary embodiments, the first thickness T1 of the first support lines 235a may be substantially the same as the second thickness T2 of the second support lines 235b. In addition, the first width W1 of the first support lines 235a may be substantially the same as the second width W2 of the second support lines 235b. Further, the first distance DS1 between the adjacent first support lines 235a may be substantially the same as the second distance DS2 between the adjacent second support lines 235b. A size of the openings 245 of the supporting layer 235 may be controlled according to the first distance DS1 between the adjacent first support lines 235a and the second distance DS2 between the adjacent second support lines 235b (e.g., a shape of the openings 245 is changeable). For example, when the first distance DS1 and the second distance DS2 are substantially the same, the openings 245 may have a planar shape of a square opening shape. In some exemplary embodiments, when the first distance DS1 of the first support lines 235a is different from the second distance DS2 of the second support lines 235b, the openings 245 may have a planar shape of a rectangular opening shape. In exemplary embodiments, a thickness of each of the first and second support lines 235a and 235b may be smaller than a width of each of the first and second support lines 235a and 235b.

In other word, resilience or elasticity of the supporting layer 235 may be controlled according to the first thickness T1, the first width W1, and the first distance DS1 of the first support lines 235a and the second thickness T2, the second width W2, and the second distance DS2 of the second support lines 235b. For example, a thickness of the supporting layer 235 may be determined according to a thickness of the elastic layer. The thickness of the supporting layer 235 may be relatively less than that of the elastic layer. That is, the supporting layer 235 may be buried in the elastic layer. When the supporting layer 235 including the mesh (e.g., a lattice) structure is buried in the elastic layer, resilience or elasticity of the protection structure may be increased.

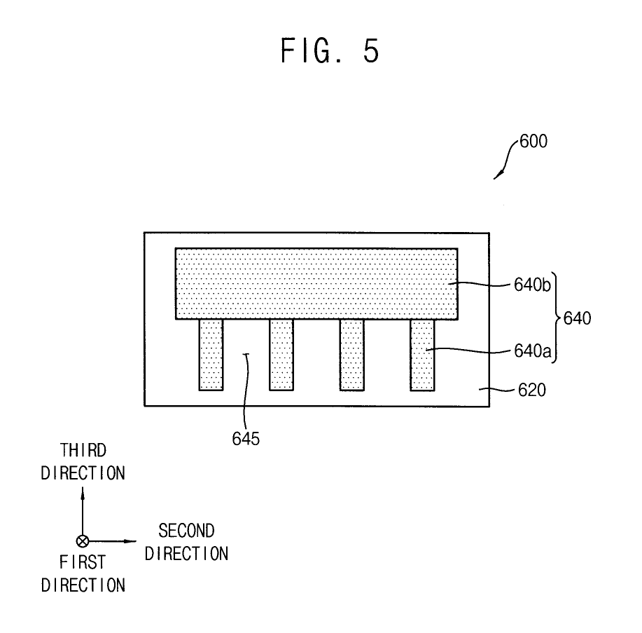

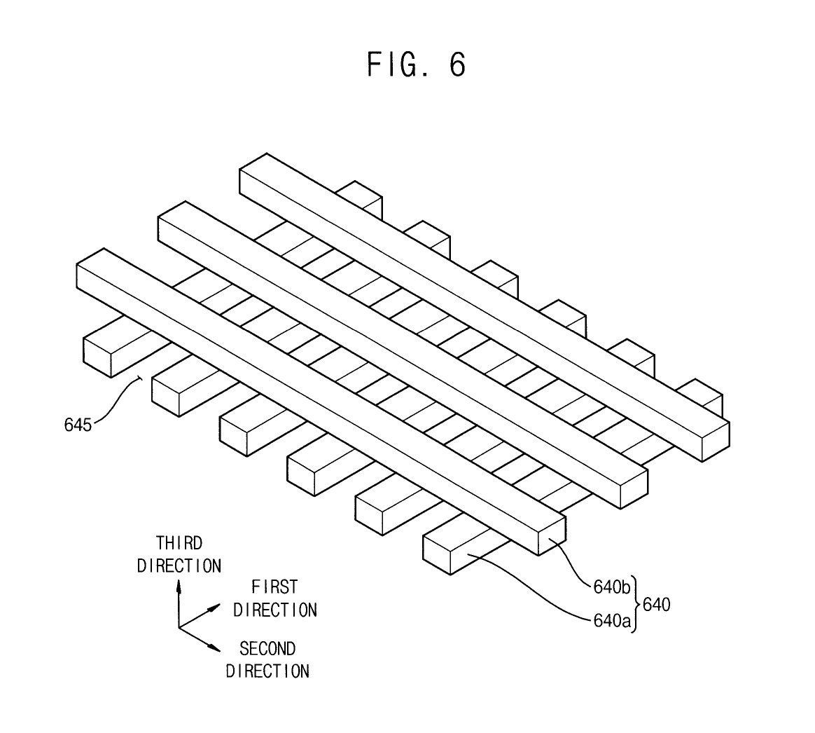

FIG. 5 is a cross-sectional view illustrating a protection structure in accordance with some exemplary embodiments, and FIG. 6 is a perspective view for describing a supporting layer of the protection structure illustrated in FIG. 5. A supporting layer 640 illustrated in FIGS. 5 and 6 may have a configuration substantially the same as or similar to that of the supporting layer 140 described with reference to FIGS. 1 through 3 except a position relationship of a first support lines 640a and a second support lines 640b. In FIGS. 5 and 6, detailed descriptions for elements, which are substantially the same as or similar to the elements described with reference to FIGS. 1 through 3, will be omitted.

Referring to FIGS. 5 and 6, a protection structure 600 may include a supporting layer 640 and an elastic layer 620. Here, the supporting layer 640 may include a plurality of supporting lines. The supporting lines may define a plurality of openings 645. That is, the supporting layer 640 may include a configuration that one opening 645 is disposed between adjacent two of the supporting lines. The plurality of supporting lines may include a plurality of first support lines 640a and a plurality of second support lines 640b. The first support lines 640a may have a first thickness and a first width. The first support lines 640a may extend along a first direction. Adjacent first support lines 640a may be spaced apart by a first distance, and may be arranged in substantially parallel to each other. The second support lines 640b may have a second thickness and a second width. The second support lines 640b may extend along a second direction that is substantially perpendicular to the first direction. Adjacent second support lines 640b may be spaced apart by a second distance, and may be arranged in substantially parallel to each other.

The first support lines 640a and the second support lines 640b may be substantially disposed at a different level. For example, the second support lines 640b may be disposed on the first support lines 640a. In addition, the first support lines 640a and the second support lines 640b may be arranged to cross each other. Accordingly, the supporting layer 640 including the first support lines 640a and the second support lines 640b may substantially have a mesh structure. The supporting layer 640 may include a super elastic metal having a relatively high resilience or a relatively high elasticity. In some exemplary embodiments, the supporting layer 640 may include an alloy, metal nitride, conductive metal oxide, a transparent conductive material, etc.

As illustrated in FIG. 6, a size of the openings 645 of the supporting layer 640 may be controlled according to the first distance between the adjacent first support lines 640a and the second distance between the adjacent second support lines 640b. In exemplary embodiments, resilience or elasticity of the supporting layer 640 may be controlled according to the first thickness, the first width, and the first distance of the first support lines 640a and the second thickness, the second width, and the second distance of the second support lines 640b. For example, a thickness of the supporting layer 640 may be determined according to a thickness of the elastic layer 620. The thickness of the supporting layer 640 may be relatively less than that of the elastic layer 620. That is, the supporting layer 640 may be buried in the elastic layer 620. In exemplary embodiments, a thickness of each of the first and second support lines 640a and 640b may be smaller than a width of each of the first and second support lines 640a and 640b.

The elastic layer 620 may bury the supporting layer 640. That is, the elastic layer 620 may substantially surround the supporting layer 640. The elastic layer 620 may include materials having a relatively high resilience or a relatively high elasticity. For example, the elastic layer 620 may include silicon, urethane, thermoplastic poly urethane (TPU), and so on.

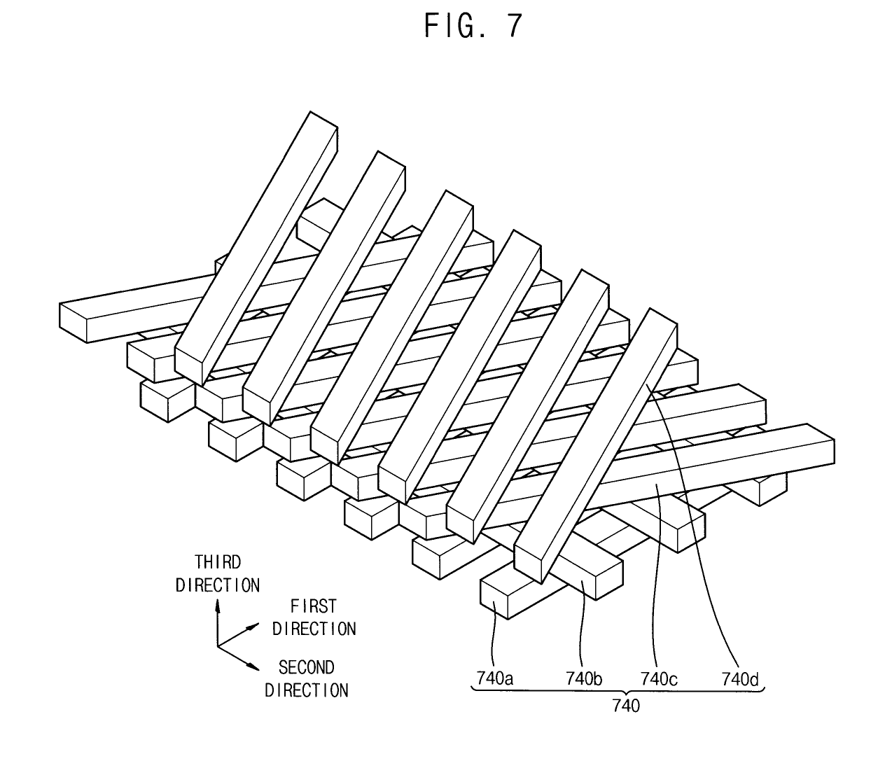

FIG. 7 is a perspective view illustrating a protection structure in accordance with some exemplary embodiments. A supporting layer 740 illustrated in FIG. 7 may have a configuration substantially the same as or similar to that of the supporting layer 640 described with reference to FIGS. 5 and 6 except a third support lines 740c and a fourth support lines 740d. In FIG. 7, detailed descriptions for elements, which are substantially the same as or similar to the elements described with reference to FIGS. 5 and 6, will be omitted.

Referring to FIG. 7, a protection structure may include a supporting layer 740 and an elastic layer. Here, the supporting layer 740 may include a plurality of supporting lines. The plurality of supporting lines may include a plurality of first support lines 740a and a plurality of second support lines 740b, a plurality of third support lines 740c, and a plurality of fourth support lines 740d. The first support lines 740a may have a first thickness and a first width. The first support lines 740a may extend along a first direction. Adjacent first support lines 740a may be spaced apart by a first distance, and may be arranged in substantially parallel to each other. The second support lines 740b may have a second thickness and a second width. The second support lines 740b may extend along a second direction that is substantially perpendicular to the first direction. Adjacent second support lines 740b may be spaced apart by a second distance, and may be arranged in substantially parallel to each other. The third support lines 740c may have a third thickness and a third width. The third support lines 740c may extend along A direction (e.g., at an angle to the first direction (approximately between 30 degree and 60 degree)) that is different from the first and second directions. Adjacent third support lines 740c may be spaced apart by a third distance, and may be arranged in substantially parallel to each other.

The fourth support lines 740d may have a fourth thickness and a fourth width. The fourth support lines 740d may extend along B direction that is substantially perpendicular to the A direction. Adjacent fourth support lines 740d may be spaced apart by a fourth distance, and may be arranged in substantially parallel to each other. In exemplary embodiments, a thickness of each of the first through the fourth support lines 740a, 740b, 740c, and 740d may be smaller than a width of each of the first through the fourth support lines 740a, 740b, 740c, and 740d.

The first through the fourth support lines 740a, 740b, 740c and 740d may be substantially disposed at a different level. For example, the second support lines 740b may be disposed on the first support lines 740a. The third support lines 740c may be disposed on the second support lines 740b. The fourth support lines 740d may be disposed on the third support lines 740c. In addition, the first support lines 740a through the fourth support lines 740d may be arranged to cross each other. Accordingly, the supporting layer 740 including the first support lines 740a through the fourth support lines 740d may substantially have another mesh structure disposed on one mesh structure. The supporting layer 740 may include a super elastic metal having a relatively high resilience or a relatively high elasticity. In some exemplary embodiments, a thickness of the supporting layer 740 may be determined according to a thickness of the elastic layer. The thickness of the supporting layer 740 may be relatively less than that of the elastic layer. That is, the supporting layer 740 may be buried in the elastic layer.

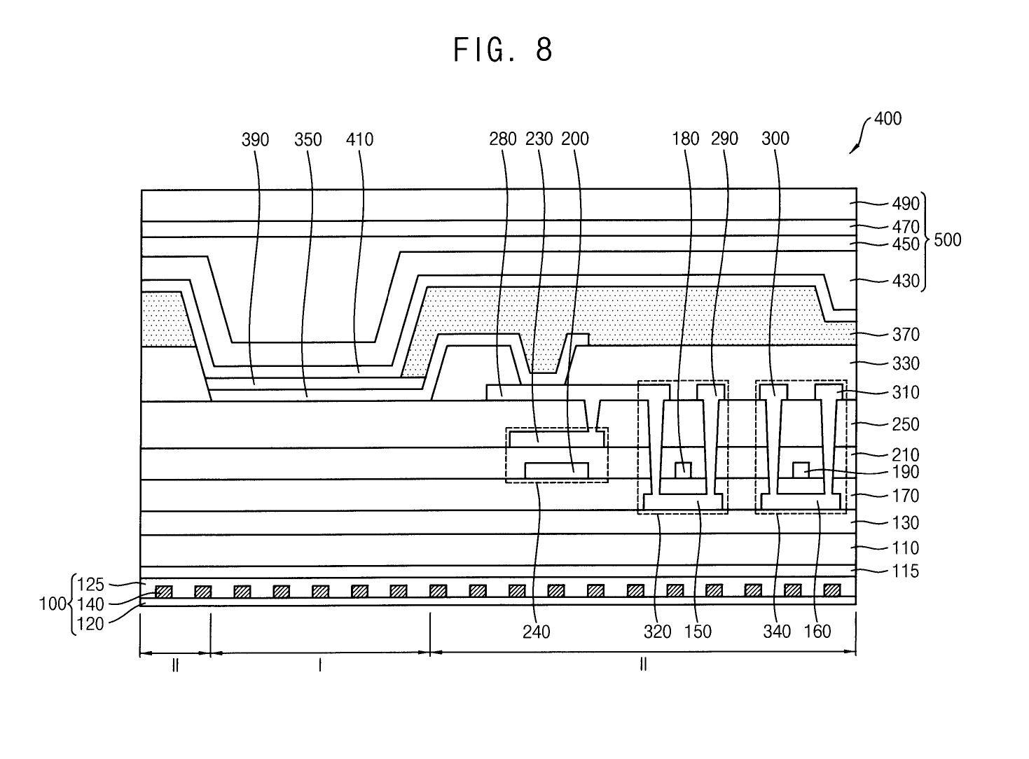

FIG. 8 is a cross-sectional view illustrating an organic light emitting display device in accordance with some exemplary embodiments.

Referring to FIG. 8, an organic light emitting display (OLED) device 400 may include a substrate 110, a protection structure 100, an adhesive film 115, a light emitting structure, an encapsulation substrate 500, etc. Here, the light emitting structure may include a driving transistor 320, a switching transistor 340, a storage capacitor 240, a first insulating layer 170, a second insulating layer 210, a planarization layer 250, a power supply electrode 280, a third insulating layer 330, a first electrode 350, a light emitting layer 390, a pixel defining layer 370, a second electrode 410, etc.

In exemplary embodiments, the OLED device 400 may include a pixel region I and a peripheral region II. In this case, the first electrode 350, the light emitting layer 390, and the second electrode 410 may be positioned in the pixel region I. In addition, the driving transistor 320, the switching transistor 340, the storage capacitor 240, the power supply electrode 280, the third insulating layer 330, and the pixel defining layer 370 may be positioned in the peripheral region II. The protection structure 100 may be positioned in the pixel region I and the peripheral region II. For example, the protection structure 100 may include a first elastic layer 120, a second elastic layer 125, and a supporting layer 140. The protection structure 100 may be combined to the OLED device 400, and thus resilience or elasticity of the OLED device 400 may be increased. Accordingly, the OLED device 400 may serve as a flexible display device.

The substrate 110 may include a transparent inorganic material or flexible plastic. As the OLED device 400 may include the pixel region I and the peripheral region II, the substrate 110 may also include the pixel region I and the peripheral region II. For example, the substrate 110 may include a glass substrate, a quartz substrate, a flexible transparent resin substrate, etc. In exemplary embodiments, the substrate 110 may be a flexible transparent resin substrate. The flexible transparent resin substrate for the substrate 110 may include a polyimide substrate. For example, the polyimide substrate may include a first polyimide layer, a barrier film layer, a second polyimide layer, etc. Alternately, the substrate 110 may have a structure in which the first polyimide layer, the barrier film layer and the second polyimide layer are stacked on a glass substrate. For example, after an insulation layer is provided on the second polyimide layer, the light emitting structure (e.g., the driving transistor 320, the switching transistor 340, the power supply electrode 280, the first electrode 350, the light emitting layer 390, the second electrode 410, etc) may be disposed on the insulation layer. After the light emitting structure is formed on the insulation layer, the glass substrate may be removed. It may be difficult that the light emitting structure is directly formed on the polyimide substrate because the polyimide substrate is thin and flexible. Accordingly, the light emitting structure is formed on a rigid glass substrate, and then the polyimide substrate may be used as the substrate 110 after a removal of the glass substrate.

The protection structure 100 may include a first elastic layer 120, a supporting layer 140, and a second elastic layer 125. In exemplary embodiments, the supporting layer 140 may be interposed between the first elastic layer 120 and the second elastic layer 125. For example, the first and second elastic layers 120 and 125 may substantially surround the supporting layer 140. Accordingly, the supporting layer 140 may be buried between the first and second elastic layers 120 and 125.

In exemplary embodiments, the supporting layer 140 of the protection structure 100 may substantially have a plate-shape. In this case, the supporting layer 140 may include a plurality of openings. For example, the openings of the supporting layer 140 may be substantially regularly arranged along a column direction or a row direction. The openings substantially have a planar shape of a substantially rectangular shape, but a shape of the openings of the supporting layer 140 is not limited thereto. For example, each of the openings of the supporting layer 140 may have various planar shapes such as a planar shape of a substantially square opening shape, a substantially diamond opening shape, a substantially triangle opening shape, a substantially circular opening shape, a substantially elliptical opening shape, a substantially track-shaped opening shape, etc.

The supporting layer 140 may be disposed in the first and second elastic layers 120 and 125. In this case, a plurality of the openings of the supporting layer 140 may be filled with the first and second elastic layers 120 and 125. For example, since the openings are filled with the first and second elastic layers 120 and 125 in a vacuum state, air may not exist in the openings. The supporting layer 140 may substantially have a mesh structure. For example, the openings may be formed in a preliminary metal plate by an etching process using a mask. The metal plate including the openings may be the supporting layer 140 in accordance with exemplary embodiments. Accordingly, as the protection structure 100 includes the supporting layer 140 having the mesh structure and the first and second elastic layers 120 and 125 in which the supporting layer 140 is buried, resilience or elasticity may be relatively increased.

The supporting layer 140 may include material such as a metal or a supporting plastic, having a relatively high resilience or a relatively high elasticity. For example, the supporting layer 140 may include an alloy such as Ni—Ti, Ni—Al, Cu—Zn—Ni, Cu—Al—Ni, Cu—Al—Mn, Ti—Ni—Cu—Mo, Co—Ni—Ga:Fe, Ag—Ni, Au—Cd, Fe—Pt, Fe—Ni, In—Cd, etc. Alternately, the supporting layer 140 may include metal nitride, conductive metal oxide, a transparent conductive material, etc. For example, the supporting layer 140 may include aluminum alloy, AlNx, WNx, CrNx, molybdenum alloy, TiNx, TaNx, SRO, ZnOx, ITO, SnOx, InOx, GaOx, IZO, etc. In addition, the first and second elastic layers 120 and 125 may include an elastomer having a relatively high resilience or a relatively high elasticity. For example, the first and second elastic layers 120 and 125 may include elastic materials such as silicon, urethane, TPU, etc. When the first elastic layer 120 includes materials the same as materials of the second elastic layer 125, the first elastic layer 120 may be substantially integrally formed with the second elastic layer 125.

The adhesive film 115 may be disposed between the substrate 110 and the protection structure 100. The adhesive film 115 may adhere to the substrate 110 and the protection structure 100. For example, the adhesive film 115 may include a double-side adhesive film, a PSA film, etc. The films may include urethane-based materials, acryl-based materials, silicon-based materials, etc. In exemplary embodiments, the adhesive film 115 may have materials the same as materials of the first elastic layer 120 and the second elastic layer 125. For example, when the supporting layer 140 directly adheres to the substrate 110 of the OLED device 400 by using a adhesive film 115, the supporting layer 140 and the substrate 110 may not bond together because materials of the supporting layer 140 is different from materials of the substrate 110. In addition, since a thickness of the substrate 110 is relatively less than that of the supporting layer 140, the supporting layer 140 may not be substantially buried in the substrate 110. However, when a thickness of the substrate 110 is increased and the supporting layer 140 is buried in the substrate 110, a problem may occur due to the supporting layer 140 buried in the substrate 110 while an light emitting structure is formed on the substrate 110. Thus, after the light emitting structure is formed on the substrate 110, the protection structure 100 including the supporting layer 140 buried in the first and second elastic layers 120 and 125 may adhere to a lower surface of the substrate 110 by using the adhesive film 115. In exemplary embodiments, when the supporting layer 140 of the protection structure 100 has the mesh (e.g., a lattice) structure and the mesh structure is buried in the first elastic layer 120 and the second elastic layer 125, resilience or elasticity of the OLED device 400 including the protection structure 100 may be increased.

When the substrate 110 and the encapsulation substrate 500 have flexible materials, the OLED device 400 having the protection structure 100 including the supporting layer 140, the first elastic layer 120, and the 125 may serve as a flexible display device. The resilience or elasticity of the OLED device 400 may be relatively increased.

The buffer layer 130 may be disposed on the substrate 110. The buffer layer 130 may prevent the diffusion (e.g., an out gassing) of metal atoms and/or impurities from the substrate 110. Additionally, the buffer layer 130 may control a rate of a heat transfer in a crystallization process for forming a first active pattern 150 and a second active pattern 160, thereby obtaining substantially uniform the first and the second active patterns 150 and 160. For example, the buffer layer 130 may include silicon nitride, silicon oxide, etc. In some exemplary embodiments, only one buffer layer or no buffer layer may be provided on the substrate 110 in accordance with the type of the substrate 110.

The driving transistor 320 may be disposed on the buffer layer 130. The driving transistor 320 may include a first active pattern 150, the first insulating 170, a first gate electrode 180, the second insulating layer 210, the planarization layer 250, a first source electrode, a first drain electrode 290, etc. Here, the first source electrode may be connected to the power supply electrode 280, and a high power supply voltage ELVDD may be applied to the first source electrode. For example, the OLED device 400 may include the power supply electrode 280 (e.g., a high power supply electrode) and a low power supply electrode (not shown). The high power supply voltage ELVDD may be provided to the power supply electrode 280, and the low power supply voltage ELVSS may be provided to the low power supply electrode.

The switching transistor 340 may be disposed on the buffer layer 130. The switching transistor 340 may include a second active pattern 160, the first insulating 170, a second gate electrode 190, the second insulating layer 210, the planarization layer 250, a second source electrode 300, a second drain electrode 310, etc.

The storage capacitor 240 may be disposed on the first insulating 170. In exemplary embodiments, the storage capacitor 240 may include a first capacitor electrode 200, the second insulating layer 210, a second capacitor electrode 230, etc. Here, the second capacitor electrode 230 may be connected to the power supply electrode 280, and the high power supply voltage ELVDD may be applied to the second capacitor electrode 230.

The driving transistor 320 and the switching transistor 340 may be positioned in the peripheral region II. In the driving transistor 320 and the switching transistor 340, the first and second active patterns 150 and 160 may be disposed spacing apart from each other by a predetermined distance in the peripheral region II on the buffer layer 130. For example, each of the first and second active patterns 150 and 160 may include oxide semiconductor, inorganic semiconductor (e.g., amorphous silicon, polysilicon, etc.), organic semiconductor, etc.

The first insulating layer 170 may be disposed on the buffer layer 130. The first insulating layer 170 may cover the first and second active patterns 150 and 160, and may extend into the pixel region I. For example, the first insulating layer 170 may include a silicon compound, a metal oxide, etc. Alternately, the first insulating layer 170 may include a material substantially the same as that of the buffer layer 130.

The first gate electrode 180 may be disposed on the first insulating layer 170 under which the first active pattern 150 is positioned. The second gate electrode 190 may be disposed on the first insulating layer 170 under which the second active pattern 160 is positioned. Each of the first gate electrode 180 and the second gate electrode 190 may include metal, alloy, metal nitride, conductive metal oxide, a transparent conductive material, etc.

The first capacitor electrode 200 may be disposed on the first insulating layer 170. The first capacitor electrode 200 may be spaced apart from the first gate electrode 180 by predetermined distances. The first capacitor electrode 200, the first gate electrode 180, and the second gate electrode 190 may include substantially the same material. Alternately, each of the first capacitor electrode 200, the first gate electrode 180, and the second gate electrode 190 may include different materials.

The second insulating layer 210 may be disposed on the first insulating layer 170, the first capacitor electrode 200, the first gate electrode 180, and the second gate electrode 190. The second insulating layer 210 may cover the first capacitor electrode 200, the first gate electrode 180, and the second gate electrode 190, and may extend into the pixel region I. For example, the second insulating layer 210 may include a silicon compound, a metal oxide, etc. Alternately, the second insulating layer 210 may include a material substantially the same as that of the buffer layer 130 and the first insulating layer 170.

The second capacitor electrode 230 may be disposed on the second insulating layer 210 under which the first capacitor electrode 200 is positioned. The second capacitor electrode 230 may include a material substantially the same as that of the first gate electrode 180, the second gate electrode 190, and the first capacitor electrode 200. Alternately, each of the second capacitor electrode 230, the first gate electrode 180, the second gate electrode 190, and the first capacitor electrode 200 may include different materials.

The planarization layer 250 may be disposed on the second insulating layer 210 and the second capacitor electrode 230. The planarization layer 250 may cover the second capacitor electrode 230, and may extend into the pixel region I. For example, the planarization layer 250 may include a silicon compound, a metal oxide, etc. In addition, a thickness of the planarization layer 250 may be substantially greater than that of the second insulating layer 210. For example, the thickness of the planarization layer 250 may be substantially greater than that of the buffer layer 130, the first insulating layer 170, and the second insulating layer 210. Thus, a coupling phenomenon which may be generated between the power supply electrode 280 and the second capacitor electrode 230 may be reduced.

A portion of the first electrode 350, the light emitting layer 390, a portion of the second electrode 410, a portion of the pixel defining layer 370, and a portion of the encapsulation substrate 500 may be positioned in the pixel region I on the planarization layer 250. The power supply electrode 280, the first source electrode of the driving transistor 320, the first drain electrode of the driving transistor 320, the second source electrode 300 of the switching transistor 340, the second drain electrode 310 of the switching transistor 340, the third insulating layer 330, a portion of the pixel defining layer 370, a portion of the first electrode 350, and a portion of the encapsulation substrate 500 may be positioned in the peripheral region II on the planarization layer 250.

The first source electrode of the driving transistor 320 and the first drain electrode 290 of the driving transistor 320 may contact the first active pattern 150 by removing portions of the planarization layer 250, the second insulating layer 210, and the first insulating layer 170. Each of the first source electrode and the first drain electrode 290 may include metal, alloy, metal nitride, conductive metal oxide, a transparent conductive material, and so on. These may be used alone or in a combination thereof.

The second source electrode 300 of the switching transistor 340 and the second drain electrode 310 of the switching transistor 340 may contact the second active pattern 160 by removing portions of the planarization layer 250, the second insulating layer 210, and the first insulating layer 170. Each of the second source electrode 300 and the second drain electrode 310 may include a material substantially the same as that of the first source electrode of the driving transistor 320 and the first drain electrode 290 of the driving transistor 320.

The power supply electrode 280 may be electrically contacted to the second capacitor electrode 230 and the first active pattern 150 via contact holes. The high power supply voltage ELVDD applied to the power supply electrode 280 may be provide to the second capacitor electrode 230 and the first active pattern 150. The power supply electrode 280 may include a material substantially the same as that of the first drain electrode 290, the second source electrode 300, and the second drain electrode 310.

The third insulating layer 330 may cover the first source electrode, the first drain electrode 290, the second source electrode 300, and the second drain electrode 310. The third insulating layer 330 may include a first opening 380 and a second opening 450. The first opening 380 of the third insulating layer 330 may be positioned in the pixel region I, and the second opening 450 of the third insulating layer 330 may be positioned in the peripheral region II. A portion of the first electrode 350 may be disposed on the first opening 380 of the third insulating layer 330. The first electrode 350 disposed in the first opening 380 may extend into the peripheral region II, and may be disposed on the second opening 450. Here, the first electrode 350 may contact a portion of the power supply electrode 280 via the second opening 450. The third insulating layer 330 may include inorganic materials or organic materials.

The first electrode 350 may be disposed on the first opening 380 of the third insulating layer 330 in the pixel region I, and may extend into the peripheral region II. Here, the first electrode 350 may be disposed on the second opening 450 of the third insulating layer 330. The first electrode 350 may include metal, alloy, metal nitride, conductive metal oxide, a transparent conductive material, etc.

The light emitting layer 390 may be disposed on the first electrode 350. The light emitting layer 390 may be formed using light emitting materials capable of generating different colors of light (e.g., a red color of light, a blue color of light, and a green color of light). Alternately, the light emitting layer 390 may generally generate a white color of light by stacking a plurality of light emitting materials capable of generating different colors of light such as a red color of light, a green color of light, a blue color of light, etc.

The pixel defining layer 370 may be disposed on a portion of the light emitting layer 390, a portion of the first electrode 350, and a portion of the third insulating layer 330. The pixel defining layer 370 interposed between the first electrode 350 and the second electrode 410 in the pixel region I may electrically insulate the first electrode 350 and the second electrode 410. The pixel defining layer 370 may include organic materials or inorganic materials. Alternately, the pixel defining layer 370 may include a material substantially the same as that of the third insulating layer 330.

The second electrode 410 may be disposed on the pixel defining layer 370 and the light emitting layer 390. For example, the second electrode 410 may be disposed as a substantially uniform thickness along a profile of the pixel defining layer 370 and the light emitting layer 390. That is, the second electrode 410 may be entirely disposed in the pixel region I and the peripheral region II. In exemplary embodiments, the second electrode 410 may include a metal, an alloy, metal nitride, conductive metal oxide, a transparent conductive material, etc.

The encapsulation substrate 500 may be disposed on the second electrode 410. The encapsulation substrate 500 may include a transparent material or flexible plastic. For example, the encapsulation substrate 500 may include a rigid glass substrate, a quartz substrate, etc. In addition, the encapsulation substrate 500 may also include a flexible transparent resin substrate. For example, to increase flexibility of the OLED device 400, the encapsulation substrate 500 may include a stacked structure where at least one organic layer and at least one inorganic layer are alternately stacked. In exemplary embodiments, the encapsulation substrate 500 may include a first inorganic layer 430, a first organic layer 450, a second inorganic layer 470, and a second organic layer 490. The first inorganic layer 430 may be disposed along a profile of the second electrode 410. The first inorganic layer 430 may protect the light emitting structure. For example, the first inorganic layer 430 may block that moisture is penetrated into the light emitting layer 390. The first organic layer 450 may be disposed on the first inorganic layer 430. For example, the first organic layer 450 may be disposed using a screen printing method. In addition, as the first organic layer 450 is disposed, an uppermost surface may be planarized. The second inorganic layer 470 may be disposed on the first organic layer 450. The second inorganic layer 470 may further block that the moisture is penetrated into the light emitting layer 390. The second organic layer 490 may be disposed on the second inorganic layer 470. As the second organic layer 490 is disposed, a thin film encapsulation (TFE) process is completed. The first inorganic layer 430 and the second inorganic layer 470 may include inorganic materials. For example, each of the first inorganic layer 430 and the second inorganic layer 470 may include silicon oxide (SiOx), silicon nitride (SiNx), silicon oxynitride (SiOxNy), silicon oxycarbide (SiOxCy), silicon carbonitride (SiCxNy), aluminium oxide (AlOx), aluminium nitride (AlNx), titanium oxide (TiOx), zinc oxide (ZnOx), etc. These may be used alone or in a combination thereof. The first organic layer 450 and the second organic layer 490 may include organic materials. For example, each of the first organic layer 450 and the second organic layer 490 may include photoresist, polyimide-based resin, acrylic-based resin, polyamide-based resin, siloxane-based resin, olefin-based resin, acrylate monomer, phenylacetylene, diamine, dianhydride, silane, parylene, polyethylene (PE), polypropylene (PP), polyethylene terephthalate (PET), epoxy resin, fluoro resin, polysiloxane, etc. Alternately, a polarization layer, a touch screen panel, etc may be additionally disposed on the encapsulation substrate 500.

The OLED device 400 in accordance with exemplary embodiments may include the transparent flexible substrate 110, the flexible encapsulation substrate 500, and the protection structure 100 having the first elastic layer 120 and the second elastic layer 125 in which the supporting layer 140 is buried. Accordingly, resilience or elasticity of the OLED device 400 may be relatively increased. In addition, the OLED device 400 may serve as a flexible display device.

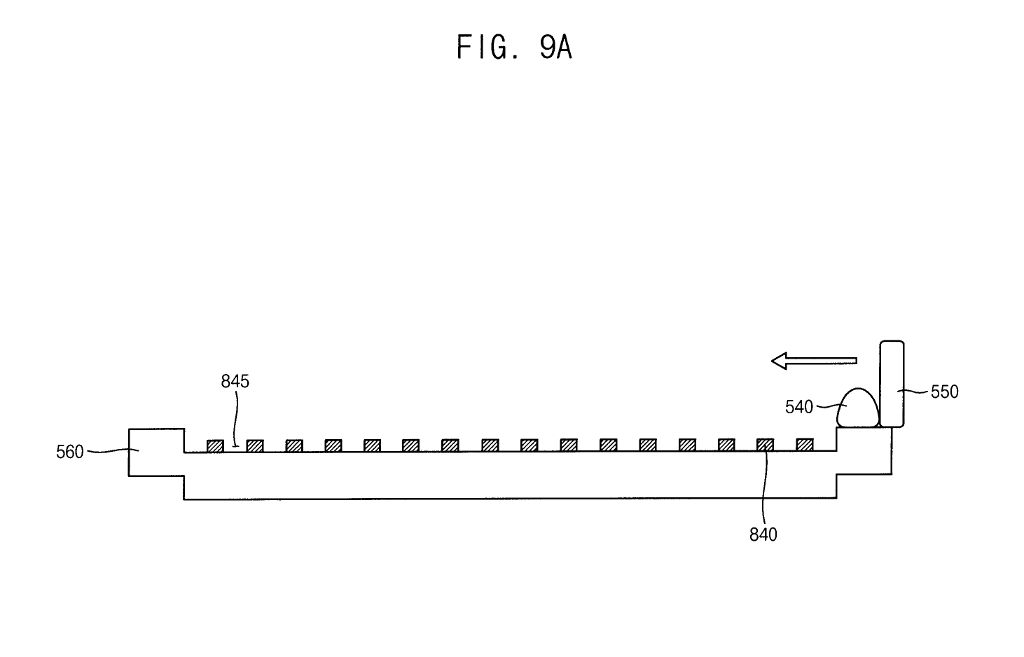

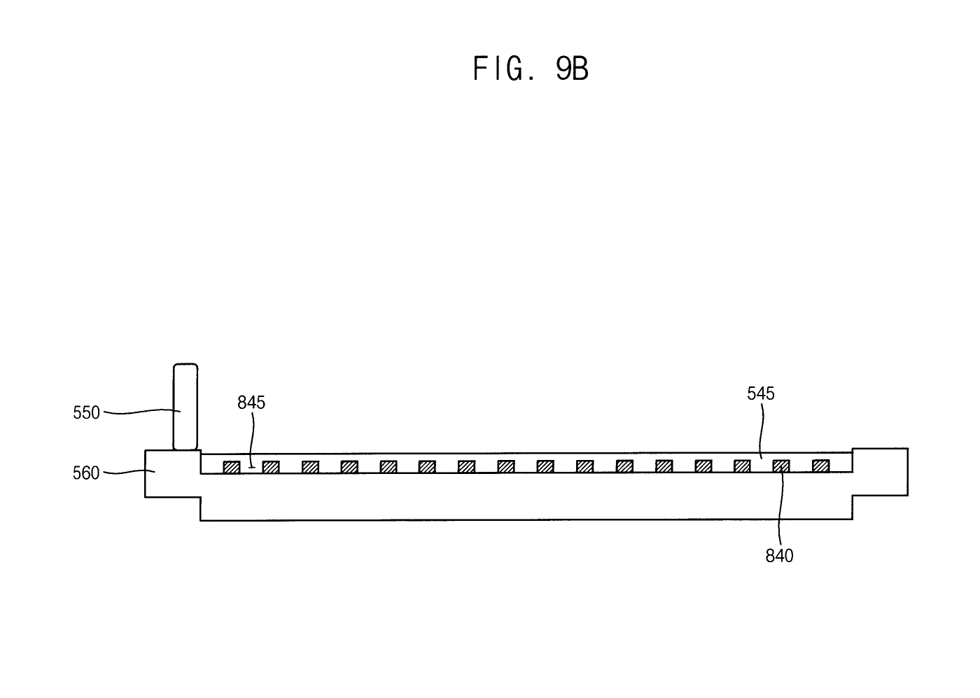

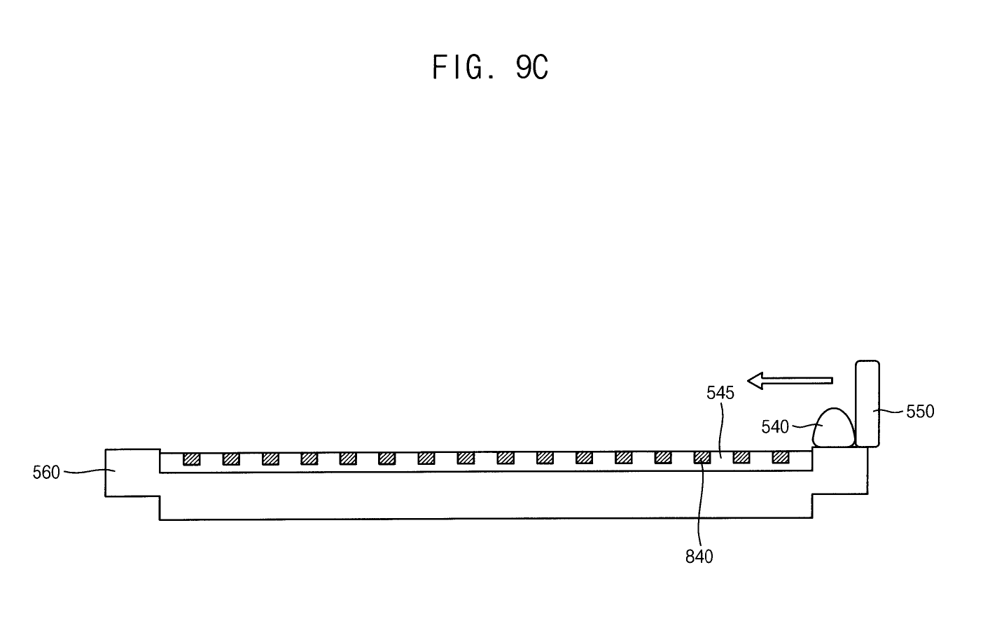

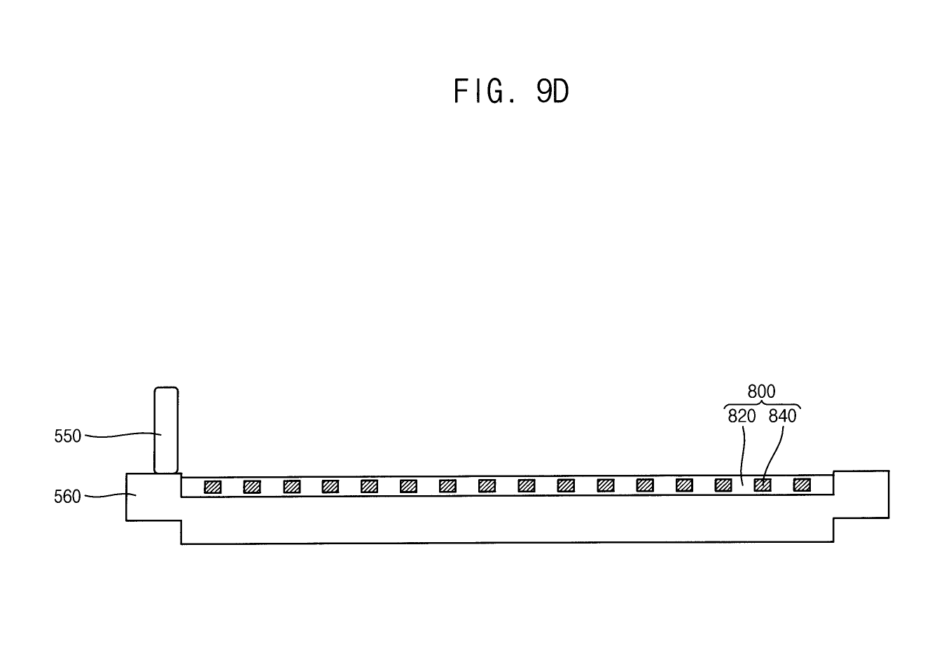

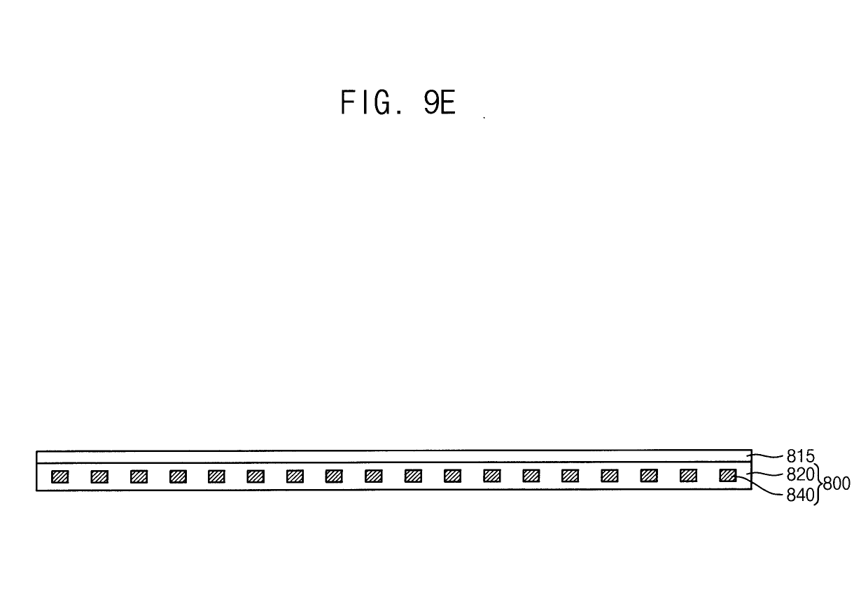

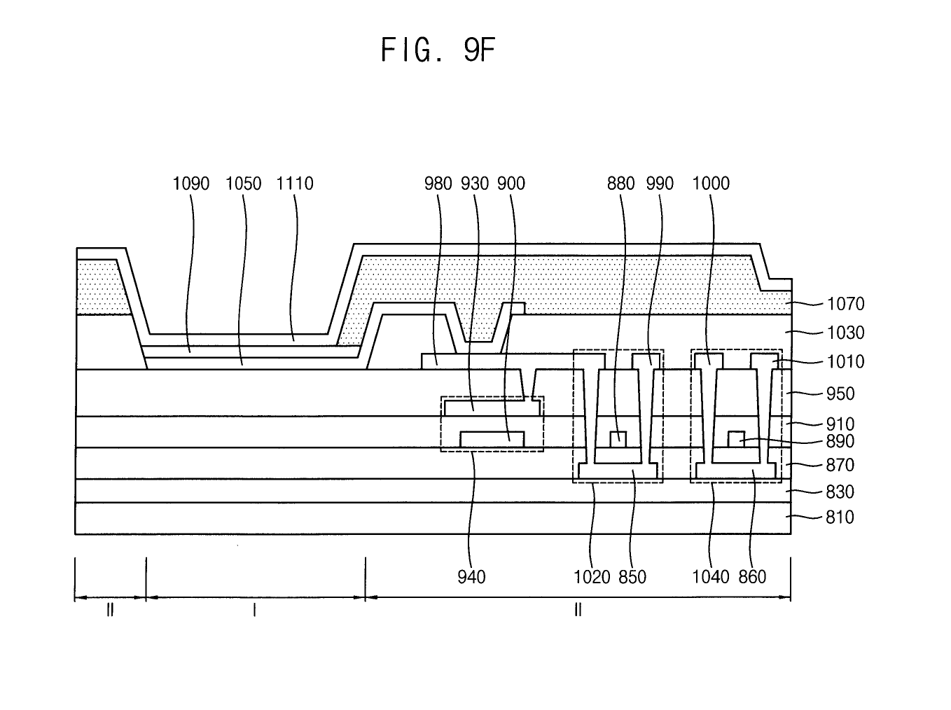

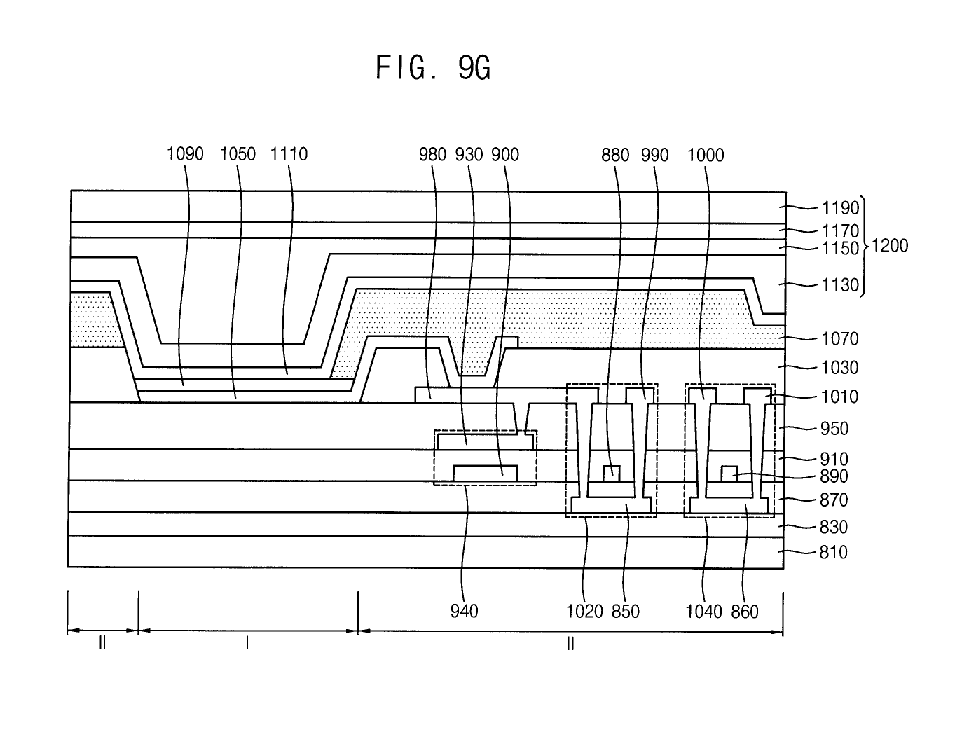

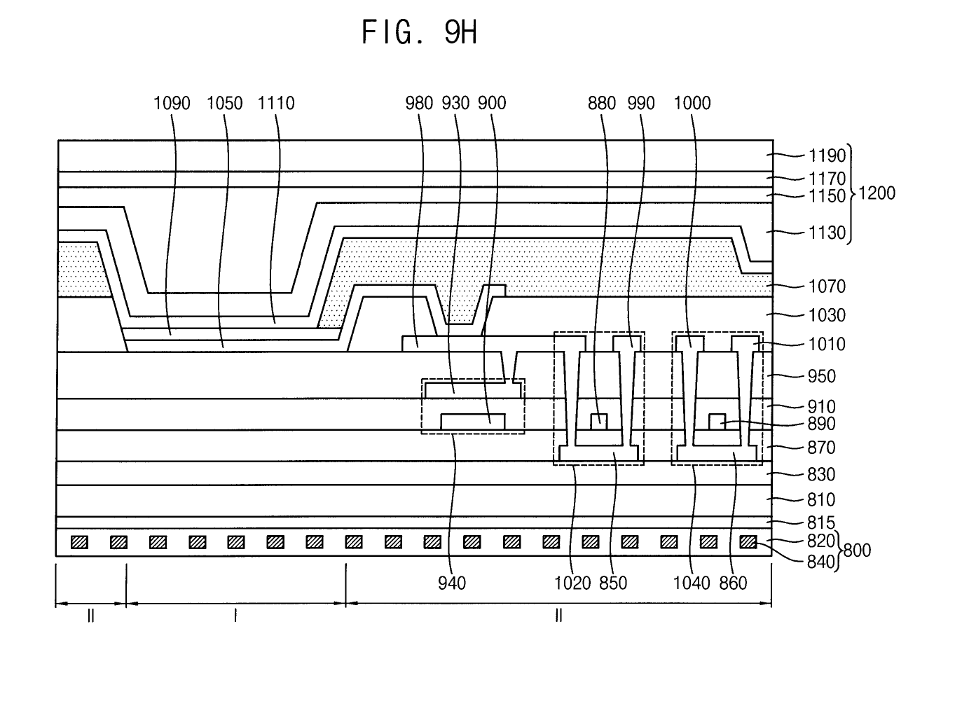

FIGS. 9A to 9H are cross-sectional views illustrating a method of manufacturing an organic light emitting display device in accordance with exemplary embodiments.

Referring to FIG. 9A, a supporting layer 840 may be positioned in an opening of a stencil plate 560. The supporting layer 840 may have a plate-shape. In this case, the supporting layer 840 may include a plurality of openings 845. For example, the openings 845 of the supporting layer 840 may be substantially regularly arranged along a column direction or a row direction. The openings 845 substantially have a planar shape of a substantially rectangular shape, but a shape of the openings 845 of the supporting layer 840 is not limited thereto. For example, each of the openings 845 of the supporting layer 840 may have various planar shapes such as a planar shape of a substantially square opening shape, a substantially diamond opening shape, a substantially triangle opening shape, a substantially circular opening shape, a substantially elliptical opening shape, a substantially track-shaped opening shape, etc. In addition, the supporting layer 840 may substantially have a mesh structure. For example, the openings 845 may be formed in a preliminary metal plate by an etching process using a mask. The metal plate including the openings 845 may be the supporting layer 840 in accordance with exemplary embodiments. The supporting layer 840 may include material such as a metal or a supporting plastic, etc having a relatively high resilience or a relatively high elasticity. For example, the supporting layer 840 may be formed using an alloy (e.g., a super elastic metal) such as Ni—Ti, Ni—Al, Cu—Zn—Ni, Cu—Al—Ni, Cu—Al—Mn, Ti—Ni—Cu—Mo, Co—Ni—Ga:Fe, Ag—Ni, Au—Cd, Fe—Pt, Fe—Ni, In—Cd, etc. Alternately, the supporting layer 840 may include metal nitride, conductive metal oxide, a transparent conductive material, etc. For example, the supporting layer 840 may be formed using aluminum alloy, AlNx, silver alloy, WNx, copper alloy, CrNx, molybdenum alloy, TiNx, TaNx, SRO, ZnOx, ITO, SnOx, InOx, GaOx, IZO, etc. An elastic material 540 having low viscosity may be positioned on a first side of the stencil plate 560. The elastic material 540 may include an elastomer having a relatively high resilience or a relatively high elasticity. For example, the elastic material 540 may use silicon, urethane, TPU, etc. A print head 550 may be disposed adjacent to the 540.

Referring to FIG. 9B, the print head 550 may be moved in a first direction from the first side of the stencil plate 560 to a second side of the stencil plate 560. While the stencil plate 560 is moved from the first side to the second side, the opening of the stencil plate 560 may be filled with the elastic material 540. That is, the elastic material 540 may fill an opening 845 of the supporting layer 840. In a spreading process of the elastic material 540, the process is performed in a vacuum state. Thus, air may not exist in the openings 845. Alternately, to cure the elastic material 540, a curing process may be added. Accordingly, a first elastic layer 545 in which a portion of the supporting layer 840 is buried may be obtained.

Referring to FIG. 9C, the first elastic layer 545 including the supporting layer 840 may be positioned in the opening of the stencil plate 560. The elastic material 540 having low viscosity may be positioned on the first side of the stencil plate 560. The print head 550 may be positioned adjacent to the elastic material 540.

Referring to FIG. 9D, the print head 550 may be moved in a first direction from the first side of the stencil plate 560 to the second side of the stencil plate 560. While the stencil plate 560 is moved from the first side to the second side, the opening of the stencil plate 560 may be filled with the elastic material 540. That is, the elastic material 540 may be formed on the supporting layer 840 and the first elastic layer 545. Accordingly, a second elastic layer may be formed on the first elastic layer 545 in which a portion of the supporting layer 840 is buried. When the first elastic layer 545 and the second elastic layer include the same materials, a protection structure 800 may be integrally formed. That is, the protection structure 800 having an elastic layer 820 in which the supporting layer 840 is buried may be obtained. In some exemplary embodiments, when the first elastic layer 545 and the second elastic layer include a different material, the protection structure 800 may be formed as two layers. Alternately, to cure the elastic layer 820, a curing process may be added.

Referring to FIG. 9E, an adhesive film 815 may be formed on the protection structure 800. For example, the adhesive film 815 may include a double-side adhesive film, a PSA film, etc. The films may be formed using urethane-based materials, acryl-based materials, silicon-based materials, etc.

Referring to FIG. 9F, a buffer layer 830 may be formed on a substrate 810, and may extend from a pixel region I into a peripheral region II. In exemplary embodiments, the substrate 810 may be formed using a flexible transparent resin substrate. The flexible transparent resin substrate for the substrate 810 may include a polyimide substrate. For example, the polyimide substrate may include a first polyimide layer, a barrier film layer, a second polyimide layer, etc. Alternately, the substrate 810 may have a structure in which the first polyimide layer, the barrier film layer and the second polyimide layer are stacked on a glass substrate. For example, after an insulation layer is provided on the second polyimide layer, a light emitting structure (e.g., a driving transistor 1020, a switching transistor 1040, a power supply electrode 980, a first electrode 1050, a light emitting layer 1090, a second electrode 1110, etc) may be formed on the insulation layer. After the light emitting structure is formed on the insulation layer, the glass substrate may be removed. It may be difficult that the light emitting structure is directly formed on the polyimide substrate because the polyimide substrate is thin and flexible. Accordingly, the light emitting structure is formed on a rigid glass substrate, and then the polyimide substrate may be used as the substrate 810 after a removal of the glass substrate.

The buffer layer 830 may be formed on the substrate 810, and may extend from the pixel region I to the peripheral region II. The buffer layer 830 may be formed using silicon nitride, silicon oxide, etc.

First and second active patterns 850 and 860 may be formed spacing apart from each other by a predetermined distance in the peripheral region II on the buffer layer 830. In exemplary embodiments, each of first and second active patterns 850 and 860 may be simultaneously formed using oxide semiconductor, inorganic semiconductor (e.g., amorphous silicon, polysilicon, etc.), organic semiconductor, etc.

A first insulating layer 870 may be formed on the buffer layer 830. The first insulating layer 870 may cover the first and second active patterns 850 and 860, and may extend into the pixel region I. For example, the first insulating layer 870 may be formed using a silicon compound, a metal oxide, etc. Alternately, the first insulating layer 870 may include a material substantially the same as that of the buffer layer 830.

A first gate electrode 880 may be formed on the first insulating layer 870 under which the first active pattern 850 is positioned. A second gate electrode 890 may be formed on the first insulating layer 870 under which the second active pattern 860 is positioned. A first capacitor electrode 900 may be formed on the first insulating layer 870. The first capacitor electrode 900 may be formed spacing apart from the first gate electrode 880 by predetermined distances. In exemplary embodiments, the first gate electrode 880, the second gate electrode 890, and the first capacitor electrode 900 may be simultaneously formed using metal, alloy, metal nitride, conductive metal oxide, a transparent conductive material, etc.

A second insulating layer 910 may be formed on the first insulating layer 870. The second insulating layer 910 may cover the first capacitor electrode 900, the first gate electrode 880, and the second gate electrode 890, and may extend into the pixel region I. For example, the second insulating layer 910 may be formed using a silicon compound, a metal oxide, etc.

As a second capacitor electrode 930 may be formed on the second insulating layer 910 under which the first capacitor electrode 900 is positioned, a storage capacitor 940 including the first capacitor electrode 900 and the second capacitor electrode 930 may be formed.

A planarization layer 950 may be formed on the second insulating layer 910. The planarization layer 950 may be formed using a silicon compound, a metal oxide, etc. The planarization layer 950 may cover the second capacitor electrode 930, and may extend into the pixel region I. Then, first through fifth contact holes may be formed in the peripheral region II of the planarization layer 950. The first contact hole may expose a first portion of the second capacitor electrode 930. The second and third contact holes may expose second and third portions of the first active pattern 850, respectively. The fourth and fifth contact holes may expose fourth and fifth portions of the second active pattern 860, respectively.

A power supply electrode 980, a first source electrode of a driving transistor 1020, a first drain electrode of the driving transistor 1020, a second source electrode 1000 of a switching transistor 1040, a second drain electrode 1010 of the switching transistor 1040 may be formed in the peripheral region II on the planarization layer 950. For example, in a forming process of the power supply electrode 980, the power supply electrode 980 fills the first contact hole, and may extend into the first contact hole. The power supply electrode 980 which extends into the first contact hole may be contacted to the first portion of the second capacitor electrode 930. At the same time, the power supply electrode 980 fills the second contact hole, and may extend into the second contact hole. The power supply electrode 980 which extends into the second contact hole may be contacted to the second portion of the first active pattern 850. Here, the first source electrode of the driving transistor 1020 may be formed. In similar, in a forming process of the first drain electrode 990, the first drain electrode 990 fills the third contact hole, and may extend into the third contact hole. The first drain electrode 990 which extends into the third contact hole may be contacted to the third portion of the first active pattern 850. Thus, the driving transistor 1020 including the first source electrode, the first drain electrode 990, the first gate electrode 880, and the first active pattern 850 may be composed.

In a forming process of the second source electrode 1000, the second source electrode 1000 is fills the fourth contact hole, and may extend into the fourth contact hole. The second source electrode 1000 which extends into the fourth contact hole may be contacted to the fourth portion of the second active pattern 860. In a forming process of the second drain electrode 1010, the second drain electrode 1010 fills the fifth contact hole, and may extend into the fifth contact hole. The second drain electrode 1010 which extends into the fifth contact hole may be contacted to the fifth portion of the second active pattern 860. Thus, the switching transistor 1040 including the second source electrode 1000, the second drain electrode 1010, the second gate electrode 890, and the second active pattern 860 may be composed. In exemplary embodiments, each of the power supply electrode 980, the first source electrode of the driving transistor 1020, the first drain electrode 990 of the driving transistor 1020, the second source electrode 1000 of the switching transistor 1040, and the second drain electrode 1010 of the switching transistor 1040 may be simultaneously formed using metal, alloy, metal nitride, conductive metal oxide, a transparent conductive material, etc.

A third insulating layer 1030 may cover the first source electrode, the first drain electrode 990, the second source electrode 1000, and the second drain electrode 1010. After the third insulating layer 1030 is entirely formed, a first opening 1080 and a second opening 1150 may be formed in the third insulating layer 1030. The first opening 1080 of the third insulating layer 1030 may be formed in the pixel region I, and the second opening 1150 of the third insulating layer 1030 may be formed in the peripheral region II. The third insulating layer 1030 may be formed using an inorganic material or an organic material.

A portion of a first electrode 1050 may be formed on the planarization layer 950 via the first opening 1080 of the third insulating layer 1030. The first electrode 1050 formed in the first opening 1080 may extend into the peripheral region II, and may be contacted to a portion of the power supply electrode 980 via the second opening 1150. The first electrode 1050 may be formed using metal, alloy, metal nitride, conductive metal oxide, a transparent conductive material, etc.

A light emitting layer 1090 may be formed in the first electrode 1050. The light emitting layer 1090 may be formed using light emitting materials capable of generating different colors of light (e.g., a red color of light, a blue color of light, and a green color of light). Selectively, the light emitting layer 1090 may generally generate a white color of light by stacking a plurality of light emitting materials capable of generating different colors of light such as a red color of light, a green color of light, a blue color of light, etc.

A pixel defining layer 1070 may be formed on a portion of the light emitting layer 1090, a portion of the first electrode 1050, and a portion of the third insulating layer 1030. The pixel defining layer 1070 may electrically insulate the first electrode 1050 and a second electrode 1110. The pixel defining layer 1070 may be formed using organic materials or inorganic materials. Alternately, the pixel defining layer 1070 may be formed using a material substantially the same as that of the third insulating layer 1030.

A second electrode 1110 may be formed on the pixel defining layer 1070 and the light emitting layer 1090. For example, the second electrode 1110 may be formed as a substantially uniform thickness along a profile of the pixel defining layer 1070 and the light emitting layer 1090. That is, the second electrode 1110 may be entirely formed in the pixel region I and the peripheral region II. In exemplary embodiments, the second electrode 1110 may be formed using a metal, an alloy, metal nitride, conductive metal oxide, a transparent conductive material, etc.

Referring to FIG. 9G, an encapsulation substrate 1200 may be formed on the second electrode 1110. The encapsulation substrate 1200 may include a transparent material or flexible plastic. For example, the encapsulation substrate 1200 may be formed using a rigid glass substrate, a quartz substrate, etc. In addition, the encapsulation substrate 1200 may also be formed using a flexible transparent resin substrate. For example, to increase flexibility of an OLED device, the encapsulation substrate 1200 may include a stacked structure where at least one organic layer and at least one inorganic layer are alternately stacked. In exemplary embodiments, the encapsulation substrate 1200 may include a first inorganic layer 1130, a first organic layer 1150, a second inorganic layer 1170, and a second organic layer 1190. The first inorganic layer 1130 may be formed along a profile of the second electrode 1010. The first inorganic layer 1130 may protect a light emitting structure. For example, the first inorganic layer 1130 may block that moisture is penetrated into the light emitting layer 1090. The first organic layer 1150 may be formed on the first inorganic layer 1130. For example, the first organic layer 1150 may be formed using a screen printing method. In addition, as the first organic layer 1150 is form, an uppermost surface may be planarized. The second inorganic layer 1170 may be formed on the first organic layer 1150. The second inorganic layer 1170 may further block that the moisture is penetrated into the light emitting layer 1090. The second organic layer 1190 may be formed on the second inorganic layer 1170. As the second organic layer 490 is formed, a TFE process is completed. The first inorganic layer 1130 and the second inorganic layer 1170 may be formed using inorganic materials. For example, each of the first inorganic layer 1130 and the second inorganic layer 1170 may include SiOx, SiNx, SiOxNy, SiOxCy, SiCxNy, AlOx, AlNx, TiOx, ZnOx, etc. These may be used alone or in a combination thereof. The first organic layer 1150 and the second organic layer 1190 may be formed using organic materials. For example, each of the first organic layer 1150 and the second organic layer 1190 may include photoresist, polyimide-based resin, acrylic-based resin, polyamide-based resin, siloxane-based resin, olefin-based resin, acrylate monomer, phenylacetylene, diamine, dianhydride, silane, parylene, PE, PP, PET, epoxy resin, fluoro resin, polysiloxane, etc. Alternately, a polarization layer, a touch screen panel, etc may be additionally formed on the encapsulation substrate 1200.

Referring to FIG. 9H, the adhesive film 815 and the protection structure 800 may be formed in a lower surface of the substrate 810.

The adhesive film 815 may adhere to the substrate 810 and the protection structure 800. For example, the adhesive film 815 may be formed using a double-side adhesive film, a PSA film, etc. The films may include urethane-based materials, acryl-based materials, silicon-based materials, etc. In exemplary embodiments, the adhesive film 815 may have materials the same as materials of the elastic layer 820. For example, when the supporting layer 840 directly adheres to the substrate 810 of the OLED device by using a adhesive film 815, the supporting layer 840 and the substrate 810 may not be bonded because materials of the supporting layer 140 is different from materials of the substrate 810. In addition, since a thickness of the substrate 810 is relatively less than that of the supporting layer 840, the supporting layer 840 may not be substantially buried in the substrate 810. However, when a thickness of the substrate 810 is increased and the supporting layer 840 is buried in the substrate 810, a problem may occur due to the supporting layer 840 buried in the substrate 810 while the light emitting structure is formed on the substrate 810. Thus, after the light emitting structure is formed on the substrate 810, the protection structure 800 including the supporting layer 840 buried in the elastic layer 820 may adhere to a lower surface of the substrate 810 by using the adhesive film 815.

The exemplary embodiments of the invention may be applied to various display devices including a flexible OLED device. For example, the exemplary embodiments of the invention may be employed in an E-paper, rollable, bendable, or foldable smart phones, smart pads, portable communication devices, display devices for display or for information transfer, a medical-display device, etc.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A protection structure comprising:
a first elastic layer;
a supporting layer disposed on the first elastic layer, including a plurality of openings; and
a second elastic layer filling the openings, being combined with the first elastic layer.

2. The protection structure of claim 1, wherein the supporting layer includes metal or plastic.

3. The protection structure of claim 1, wherein each of the first elastic layer and the second elastic layer includes elastic materials.

4. The protection structure of claim 1, wherein the first elastic layer and the second elastic layer include the same material.

5. The protection structure of claim 1, wherein the supporting layer has a plate structure.

6. The protection structure of claim 5, wherein each of the openings of the supporting layer has one selected from the group of a planar shape of a square opening shape, a rectangular opening shape and a diamond opening shape.

7. The protection structure of claim 1, wherein the supporting layer includes a plurality of support lines that are regularly crossed.

8. The protection structure of claim 7, wherein the support lines include:
a plurality of first support lines having a first thickness and a first width, extending along a first direction and being spaced apart from each other by a first distance; and
a plurality of second support lines having a second thickness and a second width, extending along a second direction perpendicular to the first direction and being spaced apart from each other by a second distance.

9. The protection structure of claim 8, wherein the second support lines are disposed on the first support lines.

10. The protection structure of claim 8, wherein the first support lines and the second support lines define a plurality of openings, and
wherein the openings are regularly arranged, having one selected from the group of a planar shape of a square opening shape, a rectangular opening shape, and a diamond opening shape.

11. The protection structure of claim 8, wherein the supporting layer further includes:
a border line connected to end portions of the first support lines and the second support lines, surrounding the first support lines and the second support lines.

12. The protection structure of claim 1, wherein the supporting layer includes a plurality of support lines that are irregularly crossed.

13. The protection structure of claim 8, wherein the support lines further include:
a plurality of third support lines having a third thickness and a third width, extending along A direction different from the first direction and the second direction, and being spaced apart from each other by a third distance.

14. The protection structure of claim 13, wherein the support lines further include:
a plurality of fourth support lines having a fourth thickness and a fourth width, extending along B direction perpendicular to the A direction, and being spaced apart from each other by a fourth distance.

15. The protection structure of claim 14, wherein the first support lines through the fourth support lines define a plurality of openings, and the openings are irregularly arranged.

16. The protection structure of claim 15, wherein a thickness of each of the first through the fourth support lines is smaller than a width of each of the first through the fourth support lines.

17. The protection structure of claim 16, wherein the openings have one selected from the group of a planar shape of a triangle opening shape, a circular opening shape, an elliptical opening shape and a track-shaped opening shape.

18. An organic light emitting display device comprising:
a protection structure including a first elastic layer, a supporting layer disposed on the first elastic layer and having a plurality of openings, and a second elastic layer filling the openings and being combined with the first elastic layer;
a substrate disposed on the protection structure;
a light emitting structure disposed on the substrate; and
an encapsulation substrate disposed on the light emitting structure.

19. The organic light emitting display device of claim 18, further comprising:
an adhesion film disposed between the protection structure and the substrate disposed on the protection structure.

20. The organic light emitting display device of claim 18, wherein the substrate disposed on the protection structure and the encapsulation substrate include materials having flexibility.
